(19) United States
(12) Patent Application Publication
(10) Pub. No.: US 2026/0172014 A1
(43) Pub. Date: Jun. 18, 2026

(54) DUTY CYCLE ADJUST WITH INDEPENDENT RISING AND FALLING EDGE CONTROL

(71) Applicant: Micron Technology, Inc., Boise, ID (US)

(72) Inventor: Jeremy Robert Kuehlwein, Woodbury, MN (US)

(21) Appl. No.: 18/986,393

(22) Filed: Dec. 18, 2024

(51) Int. Cl. H03K 5/156; G11C 7/22; H03K 5/00; H03K 5/134

(52) U.S. Cl. CPC H03K 5/1565; H03K 5/134; G11C 7/222; H03K 2005/00195

(57) ABSTRACT

A signal processing first apparatus includes a first input node configured to receive a first input signal with a first duty cycle. Multiple parallel-coupled inverter circuits can be coupled to the first input node and the first output node, with each inverter circuit including one or more control nodes. The first output node provides a first output signal that is based on the first input signal. A decoder circuit receives a first command signal and provides corresponding inverter control signals to the control nodes of the inverter circuits. Each inverter circuit can independently modify a timing characteristic of the first input signal and contribute to the first output signal.

### BACKGROUND

Duty cycle correction (DCC) circuits are used to adjust the duty cycle of datapath signals, clock signals, or other signals, for example using a delay circuit. DCC circuits can have limited adjustment resolution. While methods exist for improving adjustment resolution, they generally lead to increased power consumption, larger circuit size, or have limited adjustment range. As integrated circuits continue to decrease in size and are increasingly used in mobile devices, DCC circuits that increase power consumption or size may be impractical.

A delay line is a circuit that delays an input signal by a specified time and typically includes multiple delay cells connected in series. However, when delaying an input signal using multiple delay cells, the duty cycle of the input signal may be altered by the delay line. To address this, some delay circuits are provided with a separate duty cycle correction circuit to correct the duty cycle of the delayed input signal. The use of a separate duty cycle correction circuit increases power consumption, and the overall size and complexity of the circuit.

### SUMMARY

Solutions discussed herein include an approach for adjusting signal timing characteristics in integrated circuits by combining duty cycle adjustment and fine delay control in a single implementation. In an example, a delay and duty cycle adjustment circuit includes parallel-coupled tristate inverter stages that process true and complement signals, with each inverter stage comprising an always-on leg operating in parallel with multiple separately-controllable legs. A decoder circuit receives command signals and provides independent control of rising and falling edge timing through selective activation of pull-up and pull-down circuitry in each leg.

This systems and methods discussed herein enable both duty cycle adjustment and delay control without requiring separate delay circuits. These solutions can help reduce power consumption and minimize layout area compared to other approaches. In an example, independent control of signal edge timing enables the circuit to selectively delay either rising or falling edges or both edges of a signal. In an example, the solutions discussed herein can be particularly useful in applications such as multi-level signaling systems where precise timing alignment is critical for optimal performance.

This Summary is not intended to provide an exclusive or exhaustive explanation of the present subject matter. The Detailed Description is included to provide further information.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates generally examples of various signal timing diagrams showing signals with different duty cycle characteristics.

FIG. 2 illustrates generally an example of a schematic block diagram of a first apparatus including a first duty cycle correction circuit or DCC circuit.

FIG. 3 illustrates generally an example of a schematic block diagram of a second apparatus including a second duty cycle correction circuit or DCC circuit.

FIG. 4 illustrates generally an example of a decoder circuit.

FIG. 5 illustrates generally an example of a delay and duty cycle adjust circuit.

FIG. 6 illustrates generally an example of a first method that can include receiving an AC reference signal and, in response, providing an AC output signal with one or more rising or falling edge timing characteristics that are adjusted relative to the reference signal.

FIG. 7 illustrates generally an example block diagram of a memory system with a controller that includes a duty cycle adjust circuit.

### DETAILED DESCRIPTION

Duty cycle signal processing circuits can include duty cycle correction (DCC) or duty cycle adjustment (DCA) circuits that are used to change a characteristic of time-varying input signals (e.g., clock signals) by applying the input signals to a delay circuit. Such duty cycle processing circuits can have limited adjustment resolution. While methods exist for improving adjustment resolution, they generally lead to increased power consumption, larger circuit size, or have limited adjustment range. As integrated circuits continue to decrease in size and are increasingly used in mobile devices, duty cycle adjustment circuits that increase power consumption or size may be impractical.

In an example, a duty cycle adjustment solution uses complementary true (T) and complement (C) signal paths, each containing inverter stages for signal processing. In an example, an embodiment can include an input inverter followed by multiple parallel-coupled inverter circuits, where an always-on inverter leg operates in parallel with multiple separately-controllable legs. The controllable legs can be binary weighted or equally weighted to provide different adjustment granularity. Some solutions enable duty cycle adjustment but couple rising and falling edge adjustments, limiting flexibility in timing control. Other solutions can separate the control of rising and falling edges, enabling both duty cycle adjustment and fine delay control using the same processing circuit. By providing independent control of the true and complement signal paths, the circuit can selectively delay rising or falling edge timing, or can delay both edges. This separation of control allows for more precise timing adjustments while maintaining the efficiency of a single circuit implementation. The solutions discussed herein can be particularly advantageous in applications where layout area and power consumption must be minimized, as it eliminates the need for separate delay adjustment circuitry.

In an example, duty cycle and delay control mechanisms discussed herein use multiple parallel-coupled tri-state inverter circuits that can be selectively enabled or disabled to adjust signal propagation timing. Each inverter leg includes pull-up and pull-down circuitry that responds to independent control signals, allowing for precise adjustment of both duty cycle and overall signal delay.

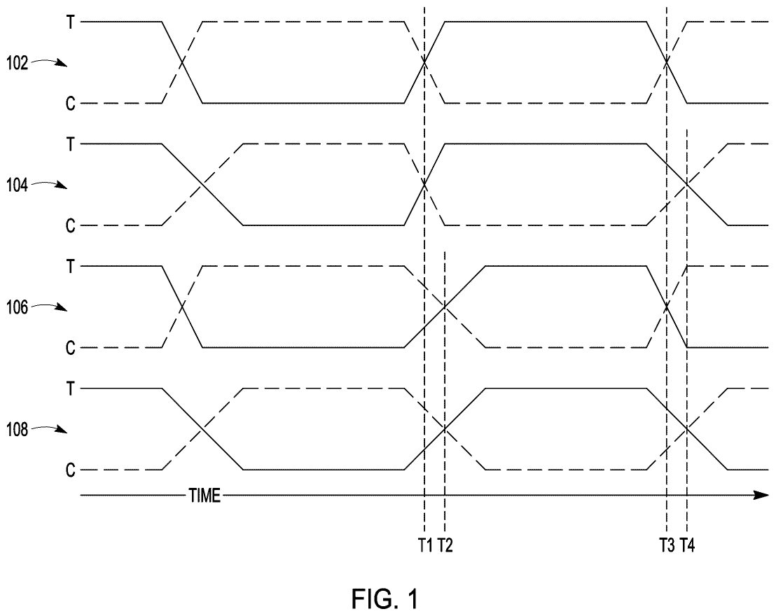

FIG. 1 illustrates generally examples of various signal timing diagrams showing signals with different duty cycle characteristics. Each of the timing diagram shows true (T) and complement (C) output signals of a differential duty cycle adjust (DCA) circuit plotted against a time axis. In the example of FIG. 1, the true signal T is shown as a solid line and the complement signal C is shown as a dashed line. In an example, the pair of T and C signals can be used together to provide noise immunity from power supply variations and other sources of interference. The timing diagrams show how timing characteristics of the true and complement signals can be adjusted to modify the duty cycle or introduce controlled delays.

Each of the true and complement signals T and C has respective rising and falling edge timing characteristics that define the respective duty cycles of these signals. In an example, the timings correspond to transitions between logic levels. Crossing points of the T and C signals in the timing diagrams of FIG. 1 can indicate the timing of transitions between logic states and can determine the duty cycle and overall signal timing.

In the example of FIG. 1, a first signal chart 102 shows a first DCA circuit output with no duty cycle adjustment and no delay adjustment selected. The first signal chart 102 provides a reference for comparison with the other signal timing diagrams in FIG. 1. In the first signal chart 102, the T signal and C signal have signal crossings at times T1 and T3 and the signals have a first duty cycle characteristic of about 50%. For convenience of discussion, in the example of the first signal chart 102, the T signal has a “rising edge” that is considered to occur at time T1 and a “falling edge” that is considered to occur at time T3. Correspondingly, the C signal has a falling edge that is considered to occur at time T1 and a rising edge that is considered to occur at time T3. Signal features other than the signal crossing, or other timing characteristics, can similarly be used to describe the timings of the signals discussed herein.

In the example of FIG. 1, a second signal chart 104 shows a second DCA circuit output with increased duty cycle relative to the example first DCA circuit output of the first signal chart 102. The positive pulsewidth of the T signal has a longer duration in the second signal chart 104 compared to the positive pulsewidth of the T signal in the first signal chart 102. The longer duration is provided by delaying the falling edge of the T signal from time T3 to time T4, and correspondingly delaying the rising edge of the C signal. In this example, the rising edge of the T signal occurs at time T1, and no delay is provided on the rising edge of the T signal and falling edge of the C signal.

In the example of FIG. 1, a third signal chart 106 shows a third DCA circuit output with decreased duty cycle relative to the example of the first DCA circuit output of the first signal chart 102. The negative pulsewidth of the T signal has a longer duration in the third signal chart 106 compared to the negative pulsewidth of the T signal in the first signal chart 102. The longer duration is provided by delaying the rising edge of the T signal from time T1 to time T2, and correspondingly delaying the falling edge of the C signal. In this example, the falling edge of the T signal occurs at time T3, and no delay is provided on the falling edge of the T signal and the rising edge of the C signal.

In the example of FIG. 1, a fourth signal chart 108 shows a fourth DCA circuit output that is delayed, and has approximately the same duty cycle, relative to the example of the first DCA circuit output of the first signal chart 102. That is, the duty cycle of the T and C signals in the fourth signal chart 108 is approximately 50%, but the rising edge of the T signal is delayed from T1 to T2, and the falling edge of the T signal is delayed from T3 to T4. In this example, logic that controls operation of the DCA circuit is configured to allow independent control of the rising edge of the T signal (along with the falling edge of the C signal), and of the falling edge of the T signal (along with the rising edge of the C signal). This control separation allows both rising and falling edges of a pulse signal to be delayed simultaneously, resulting in a fine delay adjustment while maintaining the same duty cycle as the reference signals represented in the reference signals of the first signal chart 102.

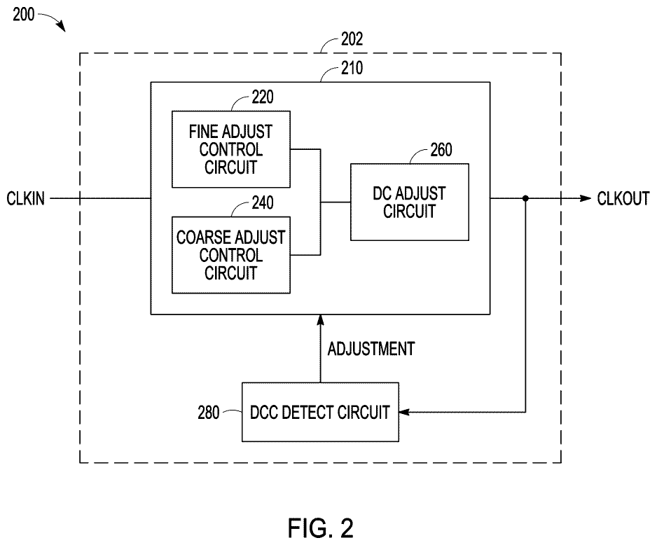

FIG. 2 illustrates generally an example of a schematic block diagram of a first apparatus 200 including a duty cycle correction circuit or DCC circuit 202. The DCC circuit 202 can include or use a duty cycle adjust circuit 260 to adjust a duty cycle of an input clock signal CLKIN to provide an output clock signal CLKOUT. In an example, the input and output clock signals comprise the complementary pair of the T signal and the complementary C signal. In other examples, the input and output clock signals are respective single signals provided without a complement.

The DCC circuit 202 can include a first signal processing circuit 210 coupled to a DCC detection circuit 280. The DCC detection circuit 280 can be configured to detect a duty cycle of the CLKOUT signal or receive one or more other control signals and, in response, provide an adjustment signal to the first signal processing circuit 210. The first signal processing circuit 210 can adjust the duty cycle of the CLKIN signal to provide the CLKOUT signal based on the adjustment signal from the DCC detection circuit 280.

In an example, the first signal processing circuit 210 includes the duty cycle adjust circuit 260, a fine adjust control circuit 220, and a coarse adjust control circuit 240. The coarse adjust control circuit 240 can provide coarse control signals to the duty cycle adjust circuit 260 to adjust a duty cycle of the CLKIN signal by a first amount (e.g., a coarse adjustment amount) using the duty cycle adjust circuit 260. The fine adjust control circuit 220 can provide fine control signals to the duty cycle adjust circuit 260 to adjust a duty cycle of the CLKIN signal by a lesser second amount (e.g., a fine adjustment amount) using the duty cycle adjust circuit 260. The first amount can be equal to one or more unit adjustments of the duty cycle adjust circuit 260 and the second amount can, in an example, be less than the unit adjustment of the duty cycle adjust circuit 260.

In an example, the duty cycle adjust circuit 260 includes a plurality of duty cycle (DC) adjust elements, such as bias controlled inverters or tristate inverters. The coarse adjust control circuit 240 can provide control signals to selectively enable or disable one or more of the plurality of DC adjust elements of the duty cycle adjust circuit 260. The unit adjustment may be equal to an adjustment of an enabled one of the DC adjust elements. The fine adjust control circuit 220 can provide a fine control signal to selectively enable or disable, or adjust a drive strength (e.g., a current drive strength), or adjust a phase interpolation of at least one of the plurality of DC adjust elements. In an example, changing the drive strength of a DC adjust element can change a delay characteristic of a signal processed using the duty cycle adjust circuit 260. In an example, a combination of the one or more DC adjust elements enabled by the coarse adjust control circuit 240 and at least one DC adjust element having an adjusted drive strength based on the fine control signal from the fine adjust control circuit 220 can adjust the duty cycle of the CLKIN signal to provide the CLKOUT signal.

In operation, the first signal processing circuit 210 can receive the CLKIN signal at an input node and, in response, provide the CLKOUT signal at an output node. The CLKOUT signal can be provided to, for example, edge sharpening circuitry or clock distribution circuitry (not shown), among other things.

The DCC detection circuit 280 can receive the CLKOUT signal from the output of the first signal processing circuit 210 (or from a different signal path) and determine a timing characteristic or duty cycle of the CLKOUT signal. In an example, in response to determining that the duty cycle of the CLKOUT signal is outside of a target duty cycle range, the DCC detection circuit 280 can provide an adjustment signal to the first signal processing circuit 210 to adjust the duty cycle of the CLKIN signal. For example, a target duty cycle may be 50%, and a target range may be some percentage within the target 50% duty cycle (e.g., +/−5%). The first signal processing circuit 210 can adjust the duty cycle of the CLKIN signal, responsive to receiving the adjustment signals, to achieve a CLKOUT duty cycle that is within the specified range of the target duty cycle.

The example of the first apparatus 200 with separate duty cycle adjust circuit 260, fine adjust control circuit 220, and coarse adjust control circuit 240 can be physically large and can consume relatively large amounts of power during operation. The present inventor has recognized that a lower-power and physically smaller solution can include or use processing circuitry that can be selectively configured to receive an input signal (e.g., an input clock signal or other AC signal) and, in response, selectively delay the input signal, change a duty cycle of the input signal, or change a delay and change a duty cycle of the input signal.

In an example, the processing circuitry can include multiple, separately-controllable signal processing elements. In an example, the processing elements include inverter circuits, and each inverter circuit can comprise an independent leg of the processing circuitry. In an example, at least two of the legs include respective inverter circuits that are coupled in parallel. The present inventor has recognized that a control scheme for the processing circuity can include or use a decoder circuit to receive a command signal and, in response, provide respective command signals to the inverter circuits to configure each of the signal processing elements for delay, duty cycle adjustment, or delay and duty cycle adjustment of the input signal.

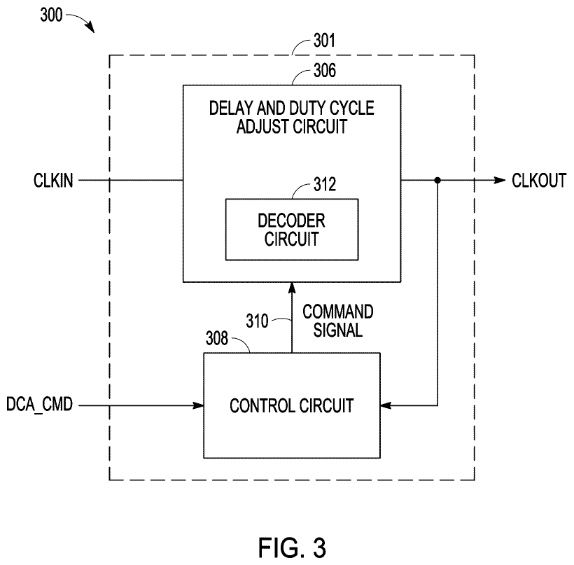

FIG. 3 illustrates generally an example of a schematic block diagram of a second apparatus 300 that includes a duty cycle correction circuit or DCC circuit 301. The DCC circuit 301 can be configured to adjust timing characteristics of the input clock signal CLKIN to provide the output clock signal CLKOUT that is based on the CLKIN signal. In an example, the DCC circuit 301 includes a delay and duty cycle adjust circuit 306 and a control circuit 308.

The delay and duty cycle adjust circuit 306 is configured to selectively change a delay, a duty cycle, or both delay and duty cycle of the input clock signal CLKIN in response to a command signal 310.

In an example, the control circuit 308 is configured to provide the command signal 310 to the delay and duty cycle adjust circuit 306. The command signal 310 can include configuration instructions for one or more elements of the delay and duty cycle adjust circuit 306. In an example, the control circuit 308 comprises a portion of a feedback control loop and the control circuit 308 can provide the command signal 310 based on sensed timing information (e.g., relative or absolute signal edge timing, duty cycle, etc.) about the output signal CLKOUT. In an example, the control circuit 308 is configured to provide the command signal 310 based on an external command, DCA_CMD, that specifies a delay and/or duty cycle adjustment for the CLKIN signal.

In an example, the delay and duty cycle adjust circuit 306 comprises multiple, parallel coupled inverter circuits, or tristate inverters. That is, each inverter circuit can comprise a different and separately-controlled leg of the signal processing circuitry that comprises the delay and duty cycle adjust circuit 306. Each of the inverter circuits can include one or more control nodes that are responsive to a portion of the command signal 310 from the control circuit 308.

In an example, the DCC circuit 301 includes a decoder circuit 312. The decoder circuit 312 can optionally comprise a portion of the control circuit 308 or the delay and duty cycle adjust circuit 306. The decoder circuit 312 can be configured to receive the command signal 310 from the control circuit 308 and, in response, provide respective control signals to each of the control nodes of each of the inverter circuits in the delay and duty cycle adjust circuit 306.

In an example, each inverter circuit instance of the parallel-coupled inverter circuits in the delay and duty cycle adjust circuit 306 is a tristate inverter. In a first state, or high-impedance state, a particular inverter can be configured by the command signal 310 to impart delay on the CLKIN signal. In a second state, the particular inverter can be configured by the command signal 310 to impart a duty cycle adjustment on a particular edge of the CLKIN signal. In a third state, the particular inverter can be configured by the command signal 310 to be substantially transparent and thus have minimal or no influence on a timing characteristic of the CLKIN signal. Each inverter circuit instance can be separately configured to any of the three states to realize various levels or durations of delay or duty cycle adjustment or both delay and duty cycle adjustment.

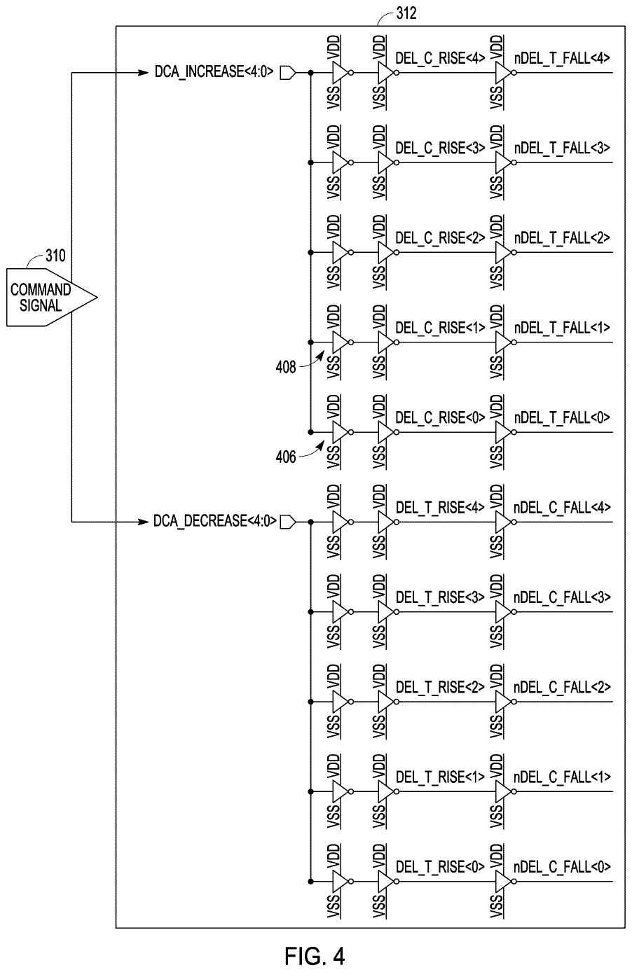

FIG. 4 illustrates generally an example of the decoder circuit 312. The decoder circuit 312 can be configured to receive the command signal 310 and, in response, provide control signals to one or more signal processing elements in the delay and duty cycle adjust circuit 306.

In an example, the command signal 310 comprises an analog or digital control signal that can be interpreted or parsed by the decoder circuit 312 to provide one or more multiple-bit digital command words. Each of the command words can specify a signal timing adjustment to be provided using a respective portion of the delay and duty cycle adjust circuit 306. For example, the decoder circuit 312 can provide a first command word, DCA_INCREASE, and a second command word, DCA_DECREASE. In an example, the first and second command words comprise the same number of bits.

Each of the bits in a command word can correspond to a control command for one or more corresponding legs of the delay and duty cycle adjust circuit 306. In an example, bits in the first command word correspond to control signals for legs of the delay and duty cycle adjust circuit 306 that can be configured to increase a duty cycle characteristic of the input signal, and bits in the second command word correspond to control signals for legs of the delay and duty cycle adjust circuit 306 that can be configured to decrease a duty cycle characteristic of the input signal. In an example, bits from each of the first and second command words can correspond to control signals for legs of the delay and duty cycle adjust circuit 306 that can be configured to provide delay.

In the example of FIG. 4, the decoder circuit 312 is configured to provide digital control signals DEL_T_RISE<#>, DEL_C_RISE<#>, nDEL_T_FALL<#> and nDEL_C_FALL<#>, where <#> indicates a particular controllable leg of the delay and duty cycle adjust circuit 306. The DEL_x_RISE control signals are logical signals that indicate whether a rising edge of the T signal or the C signal is to be delayed. The nDEL_x_FALL control signals are logical signals that indicate whether the falling edge of the T or C signal is not to be delayed. Other signals, such as conjugate signals, can similarly be used with similar processing hardware.

In an example, the decoder circuit 312 comprises multiple different strings of serial-coupled inverter circuits that are configured to provide the various digital control signals for the delay and duty cycle adjust circuit 306. A respective input of each string can correspond to a respective bit of the first or second command word (e.g., derived from or comprising a portion of the command signal 310). For example, the decoder circuit 312 includes a first string 406 that includes three serial-coupled inverter circuits, a second string 408 that includes three other serial-coupled inverter circuits, and so on. The input to the first string 406 can comprise a logic signal corresponding to a first bit of the first command word DCA_INCREASE, the input to the second string 408 can comprise a logic signal corresponding to the second bit of the first command word DCA_INCREASE, and so on. For example, if the first bit of DCA_INCREASE is a logic 1, then the input to the first string 406 is a logic 1 or high signal. If the second bit of DCA_INCREASE is a logic 0, then the input to the second string 408 is a logic 0 or low signal.

In the example of FIG. 4, the first string 406 includes a first inverter circuit that is configured as a buffer to receive the input logic signal and, in response, provide an output logic signal to a second inverter circuit. An output of the second inverter circuit provides a command signal DEL_C_RISE<#> for a corresponding leg of the delay and duty cycle adjust circuit 306. The DEL_C_RISE<#> signal is a logic signal that indicates whether a rising edge of the C signal is to be delayed or is not to be delayed using the designated leg <#>. In an example, the first string 406 includes a third inverter circuit that receives the output of the second inverter circuit and, in response, provides a command signal nDEL_T_FALL<#> for a corresponding leg of the delay and duty cycle adjust circuit 306. The nDEL_T_FALL<#> signal is a logic signal that indicates whether a falling edge of the T signal is not to be delayed using the designated leg. That is, when nDEL_T_FALL<#> is logic high, then the falling edge of the T signal is not delayed by the leg <#>.

In a particular example, the first command word, DCA_INCREASE, is represented by the five bit digital word 00001. In this example, the input to the first inverter circuit of the first string 406 is logic high, and DEL_C_RISE<0> is logic high, and nDEL_T_FALL<0> is logic low. In this example, the input to the first inverter circuit of the second string 408 is logic low, and DEL_C_RISE<1> is logic low, and nDEL_T_FALL<1> is logic high. The various other strings of inverter circuits in the decoder circuit 312 can be similarly configured.

In an example, each of the legs in the delay and duty cycle adjust circuit 306 includes signal pull-up and pull-down circuitry in each of multiple legs that can be used to adjust delay and duty cycle characteristics of an input signal. In an example, the delay and duty cycle adjust circuit 306 can be configured to provide a duty cycle decrease for an input signal. For example, when DEL_T_RISE<0> is high, then pull-up circuitry in a first leg (or leg “0”) of a T signal processing portion of the delay and duty cycle adjust circuit 306 is disabled, pull-down circuitry in the same first leg of the T signal processing portion is enabled (e.g., nDEL_T_FALL<0> is high), and the first leg is therefore configured to delay a rising edge timing of the T signal by a unit amount. In the example of the decoder circuit 312 of FIG. 4, when DEL_T_RISE<0> is high, then nDEL_C_FALL<0> is low, and pull-down circuitry in a first leg (or leg “0”) of a C signal processing portion of the delay and duty cycle adjust circuit 306 is disabled. In this example that includes a duty cycle decrease, DEL_C_RISE<0> is low, and pull-up circuitry in the first leg of the C signal processing portion of the delay and duty cycle adjust circuit 306 is enabled and therefore the leg is configured to delay a falling edge timing of the C signal. One or more other legs (e.g., up to five legs if each command word comprises five bits) of the delay and duty cycle adjust circuit 306 can be similarly controlled to further decrease the duty cycle of the input signal.

In an example, the delay and duty cycle adjust circuit 306 can be configured to provide a duty cycle increase for an input signal. For example, when DEL_T_RISE<0> is low, then pull-up circuitry in a first leg (or leg “0”) of a T signal processing portion of the delay and duty cycle adjust circuit 306 is enabled, pull-down circuitry in the same first leg of the T signal processing portion is disabled (e.g., nDEL_T_FALL<0> is low), and the first leg is therefore configured to delay a falling edge timing of the T signal by a unit amount. In the example of the decoder circuit 312 of FIG. 4, when DEL_T_RISE<0> is low, then nDEL_C_FALL<0> is high, and pull-down circuitry in a first leg (or leg “0”) of a C signal processing portion of the delay and duty cycle adjust circuit 306 is enabled. In this example that includes a duty cycle increase, DEL_C_RISE<0> is high, and pull-up circuitry in the first leg of the C signal processing portion of the delay and duty cycle adjust circuit 306 is disabled, and therefore the leg is configured to delay a rising edge timing of the C signal.

As shown in the logic of the preceding two examples, when DEL_T_RISE<#> and DEL_C_RISE<#> are oppositely valued (i.e., have respective logic values 1 and 0, or vice versa) for the same designated leg of the delay and duty cycle adjust circuit 306, then a duty cycle characteristic of the input signal is adjusted (i.e., increased or decreased) by the signal processing of the designated leg. In an example, when DEL_T_RISE<#> and DEL_C_RISE<#> are both high valued (i.e., logic 1) for the same designated leg, then the input signal is delayed by the signal processing of the designated leg. In an example when DEL_T_RISE<#> and DEL_C_RISE<#> bare both low valued (i.e., logic 0) for the same designated leg, then the input signal essentially passes through the designated leg of the delay and duty cycle adjust circuit 306 without delay or duty cycle adjustment.

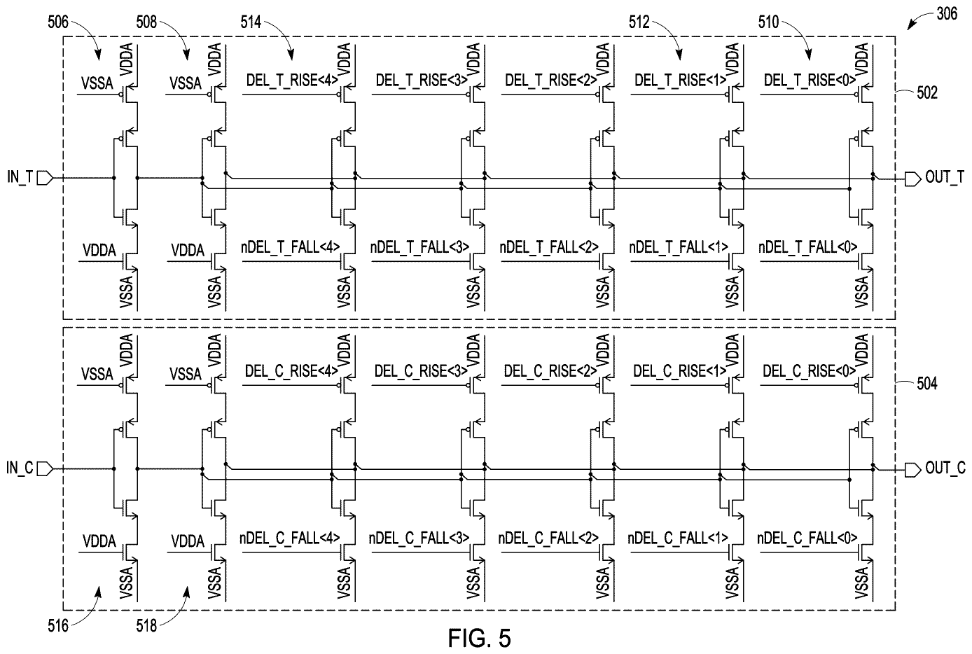

FIG. 5 illustrates generally an example of the delay and duty cycle adjust circuit 306. The example of the delay and duty cycle adjust circuit 306 comprises two parallel signal processing portions, including a first portion 502 and a second portion 504. In an example, each of the signal processing portions includes a respective input inverter and a group of parallel coupled tristate inverter circuits. Each tristate inverter stage includes complementary PMOS and NMOS transistors configured to provide controllable signal inversion and propagation delay. In an example, the input inverter in each of the first portion 502 and the second portion 504 of the delay and duty cycle adjust circuit 306 is configured as a buffer to ensure the polarity of input and output signals are the same.

The first portion 502 of the delay and duty cycle adjust circuit 306 can be configured to receive an input signal IN_T (e.g., corresponding to the T signal in prior examples) at a first node and provide an output signal OUT_T at an output node, and the output signal can have a different timing characteristic (e.g., duty cycle or delay) relative to the input signal IN_T. The second portion 504 of the delay and duty cycle adjust circuit 306 can be configured to receive an input signal IN_C (e.g., corresponding to the C signal in prior examples) and provide an output signal OUT_C with a different timing characteristic (e.g., duty cycle, or delay, or both duty cycle and delay) relative to the input signal IN_C. In an example, the input signals can comprise a pair of complementary AC or other time-varying signals, and the output signals can comprise a corresponding pair of complementary signals.

In an example, the tristate inverters in each leg of the delay and duty cycle adjust circuit 306 are configured to receive control signals from the decoder circuit 312. In response to respective control signals from the decoder circuit 312, each of the tristate inverter circuits can be independently and separately configured to be off (i.e., have a high-impedance characteristic) or on to thereby change a timing characteristic of the signal to be processed.

In an example, each of the first portion 502 and the second portion 504 of the delay and duty cycle adjust circuit 306 comprises multiple legs, and each leg includes a respective different instance of an inverter circuit (e.g., a tristate inverter circuit). The different inverter circuits can be similarly or differently configured. For example, each inverter can be similarly weighted, sized, or otherwise configured. In other examples, two or more of the inverters can be differently weighted, sized, or otherwise differently configured.

In an example, the first portion 502 of the delay and duty cycle adjust circuit 306 includes a first input inverter 506 configured to receive the input signal IN_T. The first input inverter 506 can be configured to provide a buffered output to an input of a first always-on inverter 508. The first always-on inverter 508 is configured to provide a minimum bias or drive signal to one or more other legs of the first portion 502 of the delay and duty cycle adjust circuit 306. In an example, the first always-on inverter 508 is coupled in parallel with the one or more other legs of the first portion 502 of the delay and duty cycle adjust circuit 306.

In an example, each of the legs of the first portion 502 of the delay and duty cycle adjust circuit 306 is coupled between the same power supply (e.g., VDDA) and reference (e.g., VSSA) nodes. For example, each leg can include respective PMOS transistors connected to VDDA and NMOS transistors connected to VSSA, with their gates controlled by the respective delay control signals from the decoder circuit 312. Each leg can further include other respective PMOS and NMOS devices with their gates controlled by the input signal IN_T. Each of the parallel-coupled devices can be coupled to an output node of the first portion 502 to provide the output signal OUT_T.

In the example of the first portion 502 of FIG. 5, the tristate inverter legs of the delay and duty cycle adjust circuit 306 are controlled by DEL_T_RISE<#> signals for the PMOS transistors and nDEL_T_FALL<#> signals for the NMOS transistors. Similarly, in the second portion 504 or complement signal processing path of the delay and duty cycle adjust circuit 306, the legs are controlled by DEL_C_RISE<#>and nDEL_C_FALL<#> signals from the decoder circuit 312.

In the example of FIG. 5, the first portion 502 includes a first inverter leg 510, a second inverter leg 512, and an nth inverter leg 514 or fifth inverter leg all coupled in parallel. Although five parallel-coupled inverter legs are shown, additional or fewer legs can similarly be used. In an example, additional legs can be used to increase the depth or magnitude of signal timing control that can be realized using an instance of the delay and duty cycle adjust circuit 306. When five legs are used, for example, there are 2\hat{ }5=32 combinations of different duty cycle and delay timing adjustments that can be realized. Other timing control granularity characteristics can be controlled, for example, by changing a relative weighting of one or more of the legs, such as by increasing a physical size of one or more of devices that comprise the pull-up or pull-down circuitry of a particular leg.

In the illustrated example of FIG. 5, the first inverter leg 510 receives logic control signals DEL_T_RISE<0> and nDEL_T_FALL<0> from the decoder circuit 312. The second inverter leg 512 receives logic control signals DEL_T_RISE<1> and nDEL_T_FALL<1> from the decoder circuit 312, and so on. In this way, each of the inverter legs can be separately and independently configured to contribute to a delay or other timing adjustment of the output signal OUT_T relative to the input signal IN_T.

The second portion 504 of the delay and duty cycle adjust circuit 306 is configured to receive an input signal IN_C at a second input node and provide an output signal OUT_C at a second output node. Similarly to the first portion 502, the second portion 504 of the delay and duty cycle adjust circuit 306 includes a second input inverter 516 and a second always-on inverter 518 coupled to multiple parallel-coupled tristate inverter circuits that are individually configured to provide timing adjustments.

In the second portion 504 of the delay and duty cycle adjust circuit 306, the tristate inverter legs are controlled by DEL_C_RISE<#> signals for the pull-up circuitry (e.g., PMOS transistors) and nDEL_C_FALL<#> signals for the pull-down circuitry (e.g., NMOS transistors). Each leg includes respective PMOS transistors connected to VDDA and NMOS transistors connected to VSSA, with their gates controlled by these respective delay control signals from the decoder circuit 312. When the control signals configure the legs for duty cycle adjustment or delay, the second portion 504 processes the complement input signal IN_C in coordination with the processing of the true input signal IN_T by the first portion 502 of the delay and duty cycle adjust circuit 306 to maintain proper differential operation.

In an example, tristate inverters are used in the delay and duty cycle adjust circuit 306 to allow each leg to be effectively enabled or disabled based on the control signals. When a leg is enabled, it contributes to the overall drive strength of the inverter stage, affecting the propagation delay. The legs can be binary weighted or equally weighted, meaning their relative drive strengths can be scaled to provide different delay step sizes.

In operation, when delay control signals are asserted, the delay and duty cycle adjust circuit 306 selectively enables or disables specific tristate inverter legs. For example, to delay a rising edge, the corresponding PMOS control signals (DEL_T_RISE or DEL_C_RISE) are used to reduce the pull-up strength, while to delay a falling edge, the NMOS control signals (nDEL_T_FALL or nDEL_C_FALL) are used to reduce the pull-down strength. This selective control of individual legs allows for precise adjustment of edge timing and optional delay through independent control of rising and falling edge timing for each signal.

In an alternative implementation, rather than using complementary PMOS and NMOS transistors in each leg of the delay and duty cycle adjust circuit 306, the circuitry can be configured to use only PMOS transistors or only NMOS transistors. When using only PMOS transistors, the circuit operates entirely through pull-up control, creating positive-only adjustments to timing characteristics. Conversely, when using only NMOS transistors, the circuit operates through pull-down control, providing negative-only adjustments. This alternative architecture can reduce circuit complexity while still enabling both duty cycle adjustment and fine delay control, though with potentially reduced flexibility compared to the illustrated embodiments. The decoder circuit 312 would be correspondingly updated to provide control signals appropriate for the single-type transistor configuration.

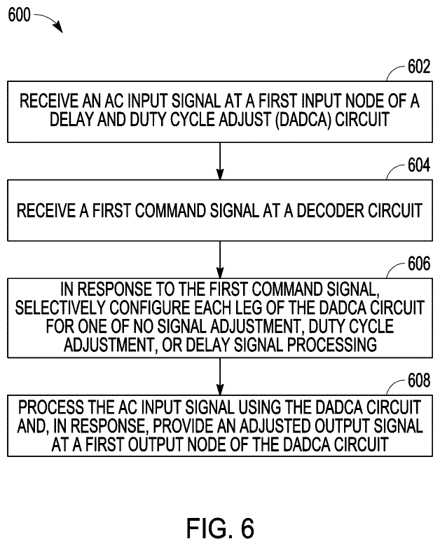

FIG. 6 illustrates generally an example of a first method 600 that can include receiving an AC reference signal and, in response, providing an AC output signal with one or more rising or falling edge timing characteristics that are adjusted relative to the reference signal. In an example, the first method 600 can be performed at least in part using the decoder circuit 312 or the delay and duty cycle adjust circuit 306 discussed herein.

At operation 602, the first method 600 includes receiving an AC input signal at a first input node of a delay and duty cycle adjust (DADCA) circuit, such as the delay and duty cycle adjust circuit 306. In an example, the DADCA circuit includes multiple parallel-coupled inverter circuits.

At operation 604, the first method 600 includes receiving a first command signal at a decoder circuit, such as the decoder circuit 312. In an example, operation 604 can include receiving a multiple-bit command signal at a decoder circuit and, using the decoder circuit, providing a respective pair of control signals to each inverter circuit of the parallel-coupled inverter circuits of the DADCA circuit.

At operation 606, the first method 600 includes, in response to the first command signal, selectively configuring each of the parallel-coupled inverter circuits of the DADCA circuit for one of no signal adjustment, duty cycle adjustment, or delay signal processing of the AC reference signal. In an example, operation 606 can include configuring at least one of the inverter circuits for duty cycle adjustment and configuring at least one other of the inverter circuits for delay signal processing.

At operation 608, the first method 600 includes processing the AC reference signal using the parallel-coupled inverters of the DADCA circuit and, in response, providing an output signal at a first output node of the DADCA circuit. The output signal can have timing characteristics that are different than corresponding characteristics of the input or AC reference signal. For example, a rising edge and/or falling edge of the output signal can be delayed relative to the reference signal, or a duty cycle characteristic of the output signal can be different than the duty cycle of the reference signal.

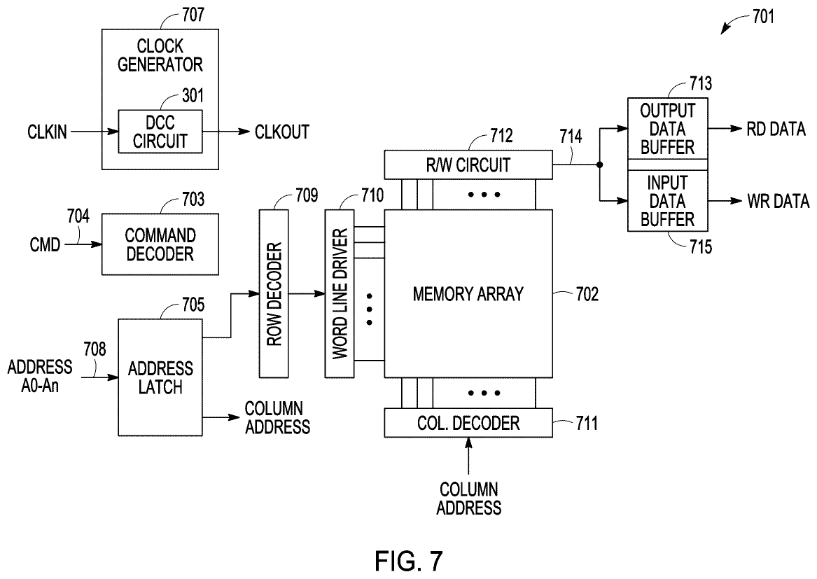

FIG. 7 illustrates generally an example block diagram of a memory system 701 with a controller that includes a duty cycle adjust circuit. The memory system 701 can include an array 702 of memory system cells. The memory cells can be, for example, volatile memory cells (e.g., DRAM memory cells, SRAM memory cells, etc.) or non-volatile memory cells (e.g., flash memory cells, phase change memory cells, etc.). The memory system 701 includes a command decoder 703 that may receive memory system commands (e.g., read, write, etc.) using a command bus 704 and provide corresponding control signals within the memory system 701 to carry out various memory system operations. For example, the command decoder 703 may respond to memory system commands provided to the command bus 704 to perform various operations on the memory system array 702. In an example, the command decoder 703 can provide internal control signals to read data from and write data to the memory system array 702. Row and column address signals can be provided to an address latch 705 in the memory system 701 using an address bus 708. The address latch 705 can then provide a separate column address and a separate row address.

The address latch 705 can provide row and column addresses to a row address decoder 709 and a column address decoder 711, respectively. The column address decoder 711 can select bit lines extending through the array 702 corresponding to respective column addresses. The row address decoder 709 can be connected to a word line driver 710 that activates respective rows of memory system cells in the array 702 corresponding to received row addresses. The selected data line (e.g., a bit line or bit lines) corresponding to a received column address may be coupled to read/write circuitry 712 to provide read data to an output data buffer 713 via an input-output data path 714. Write data may be provided to the memory system array 702 through an input data buffer 715 and the memory system array read/write circuitry 712.

In an example, the memory system 701 includes a clock generator 707 that includes a duty cycle correction circuit or duty cycle adjustment circuit. In an example, the clock generator 707 includes the DCC circuit 301 from the example of FIG. 3, such as can include the decoder circuit 312 and the delay and duty cycle adjust circuit 306. The DCC circuit 301 can be configured to provide an output clock signal CLKOUT that can be used for clocking circuitry of the memory system 701. Settings for the DCC circuit 301, such as including the particular command words used to selectively enable or disable various legs of the delay and duty cycle adjust circuit 306, can be determined using a calibration routine, such as to compensate for non-idealities in the clock generator 707 or elsewhere in the memory system 701.

To better illustrate the methods and apparatuses described herein, such as can be used to adjust a timing characteristic of an AC input signal, a non-limiting set of Example embodiments are set forth below as numerically identified Examples.

Example 1 is a signal processing apparatus comprising: a first input node configured to receive a first input signal having a first duty cycle; multiple parallel-coupled inverter circuits coupled to the first input node and to a first output node, wherein each of the inverter circuits comprises a respective control node, and wherein the first output node is configured to provide a first output signal based on the first input signal; and a decoder circuit configured to receive a first command signal and, in response, provide respective inverter control signals to each of the control nodes of the inverter circuits; wherein each of the inverter circuits is independently configured by its corresponding inverter control signal from the decoder circuit to change a timing characteristic of the first input signal and provide a portion of the first output signal.

In Example 2, the subject matter of Example 1 optionally includes each of the multiple parallel-coupled inverter circuits is a tristate inverter circuit.

In Example 3, the subject matter of any one or more of Examples 1-2 optionally includes each of the inverter circuits is independently configured by its corresponding inverter control signal from the decoder circuit to change a timing characteristic of at least one of a rising edge or a falling edge of the first input signal to provide the portion of the first output signal.

In Example 4, the subject matter of Examples 1-3 optionally includes, in response to the first command signal, the multiple parallel-coupled inverter circuits provide the first output signal as a delayed version of the first input signal.

In Example 5, the subject matter of Example 4 optionally includes, in response to a different second command signal, the multiple parallel-coupled inverter circuits provide the first output signal as a duty cycle-adjusted version of the first input signal.

In Example 6, the subject matter of Example 5 optionally includes, in response to a different third command signal, the multiple parallel-coupled inverter circuits provide the first output signal as a delayed and duty cycle-adjusted version of the first input signal.

In Example 7, the subject matter of any one or more of Examples 1-6 optionally includes each of the inverter circuits comprises a respective pair of control nodes, and the decoder circuit is configured to provide the inverter control signals, based on the first command signal, to each of the control nodes of each inverter circuit.

In Example 8, the subject matter of Example 7 optionally includes each inverter circuit comprises respective pull-up circuitry responsive to a signal at a first control node and each inverter circuit comprises respective pull-down circuitry responsive to a signal at a second control node.

In Example 9, the subject matter of Example 8 optionally includes a particular inverter circuit of the multiple parallel-coupled inverter circuits is configured to delay the first input signal when the pull-up and pull-down circuitry are each off, and wherein the particular inverter circuit is configured to change a duty cycle of the first input signal when one of the pull-up and pull-down circuitry is on, and the other one of the pull-up and pull-down circuitry is off.

In Example 10, the subject matter of any one or more of Examples 1-9 optionally includes the first command signal comprises a first command word that defines a magnitude of a delay or duty cycle increase for the first input signal, and the first command signal comprises a second command word that defines a magnitude of a delay or duty cycle decrease for the first input signal.

In Example 11, the subject matter of any one or more of Examples 1-10 optionally includes at least one of the multiple parallel-coupled inverter circuits is biased to an always-on configuration.

In Example 12, the subject matter of any one or more of Examples 1 -11 optionally includes at least two of the multiple parallel-coupled inverter circuits are differently weighted.

Example 13 is a method comprising: receiving an AC input signal at a first input node of a delay and duty cycle adjust (DADCA) circuit, wherein the DADCA circuit includes, multiple parallel-coupled inverter circuits; receiving a first command signal; in response to the first command signal, selectively configuring each of the parallel-coupled inverter circuits of the DADCA circuit for one of no signal adjustment, duty cycle adjustment, or delay signal processing; and processing the AC input signal using the parallel-coupled inverter circuits and, in response, providing an output signal at a first output node of the DADCA circuit.

In Example 14, the subject matter of Example 13 optionally includes selectively configuring each of the inverter circuits includes configuring at least one of the inverter circuits for duty cycle adjustment and configuring at least one other of the inverter circuits for delay signal processing; and wherein providing the output signal includes providing a signal that is delayed in time and duty cycle adjusted relative to the AC input signal.

In Example 15, the subject matter of any one or more of Examples 13-14 optionally includes receiving the first command signal includes: receiving a multiple-bit command signal at a decoder circuit; and using the decoder circuit, for each respective bit of the multiple-bit command signal, providing a respective pair of control signals to each inverter circuit of the parallel-coupled inverter circuits of the DADCA circuit.

In Example 16, the subject matter of Example 15 optionally includes when the pair of control signals commands a particular inverter circuit to a high-impedance first state, the output signal is delayed relative to the AC input signal, and when the pair of control signals commands the particular inverter circuit to a second state, the output signal is duty cycle adjusted relative to the AC input signal.

In Example 17, the subject matter of any one or more of Examples 13-16 optionally includes receiving the first command signal includes receiving a first multiple-bit command signal indicative of a magnitude of a duty cycle increase and receiving a second multiple-bit command signal indicative of a magnitude of a duty cycle decrease. In Example 17, the method can further include using a decoder circuit, for each respective bit of the first multiple-bit command signal, providing corresponding control signals to each of multiple inverter circuits in a first portion of the DADCA circuit, wherein the first portion of the DADCA circuit is configured to process the received AC input signal and provide a first output signal; and using the decoder circuit, for each respective bit of the second multiple-bit command signal, providing corresponding to control signals to each of multiple inverter circuits in a second portion of the DADCA circuit, wherein the second portion of the DADCA circuit is configured to process a signal complementary to the AC input signal and provide a second output signal.

In Example 18, the subject matter of any one or more of Examples 13-17 includes receiving a complementary input signal at a second input node of the DADCA circuit, wherein first and different second portions of the DADCA circuit are configured to process the AC input signal and the complementary input signal, respectively, and processing the complementary input signal using the second portion of the DADCA circuit, and providing a complementary output signal at a second output node of the DADCA circuit.

Example 19 is a signal processing circuit comprising: a first delay and duty cycle adjustment (DADCA) circuit comprising: a first input node configured to receive a first input signal having a first duty cycle; and a first instance of multiple parallel-coupled inverter circuits coupled to the first input node and to a first output node, wherein each of the inverter circuits comprises a respective pair of control nodes, and wherein the first output node is configured to provide a first output signal based on the first input signal; a second delay and duty cycle adjustment (DADCA) circuit comprising: a second input node configured to receive a second input signal that is complementary to the first input signal; and a second instance of multiple parallel-coupled inverter circuits coupled to the second input node and to a second output node, wherein each of the inverter circuits comprises a respective pair of control nodes, and wherein the second output node is configured to provide a second output signal based on the second input signal; and a decoder circuit configured to receive a first command signal and, in response, provide respective inverter circuit control signals to each of the control nodes in the first and second instances of the multiple parallel-coupled inverter circuits; wherein each of the inverter circuits is separately configured by its corresponding control signals from the decoder circuit to change a timing characteristic of the first input signal or the second input signal to provide the first and second output signals.

In Example 20, the subject matter of Example 19 optionally includes the first command signal comprises a first command word that defines a magnitude of a delay or duty cycle adjustment provided by the first DADCA circuit, and the first command signal comprises a second command word that defines a magnitude of a delay or duty cycle adjustment provided by the second DADCA circuit.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Each of these non-limiting examples can stand on its own, or can be combined in various permutations or combinations with one or more of the other examples.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” can include “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skill in the art upon reviewing the above description. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim.

Rather, inventive subject matter can lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A signal processing apparatus comprising:
a first input node configured to receive a first input signal having a first duty cycle;
multiple parallel-coupled inverter circuits coupled to the first input node and to a first output node, wherein each of the inverter circuits comprises a respective control node, and wherein the first output node is configured to provide a first output signal based on the first input signal; and
a decoder circuit configured to receive a first command signal and, in response, provide respective inverter control signals to each of the control nodes of the inverter circuits;
wherein each of the inverter circuits is independently configured by its corresponding inverter control signal from the decoder circuit to change a timing characteristic of the first input signal and provide a portion of the first output signal.

2. The signal processing apparatus of claim 1, wherein each of the multiple parallel-coupled inverter circuits is a tristate inverter circuit.

3. The signal processing apparatus of claim 1, wherein each of the inverter circuits is independently configured by its corresponding inverter control signal from the decoder circuit to change a timing characteristic of at least one of a rising edge or a falling edge of the first input signal to provide the portion of the first output signal.

4. The signal processing first apparatus of claim 1, wherein in response to the first command signal, the multiple parallel-coupled inverter circuits provide the first output signal as a delayed version of the first input signal.

5. The signal processing first apparatus of claim 4, wherein in response to a different second command signal, the multiple parallel-coupled inverter circuits provide the first output signal as a duty cycle-adjusted version of the first input signal.

6. The signal processing first apparatus of claim 5, wherein in response to a different third command signal, the multiple parallel-coupled inverter circuits provide the first output signal as a delayed and duty cycle-adjusted version of the first input signal.

7. The signal processing first apparatus of claim 1, wherein each of the inverter circuits comprises a respective pair of control nodes, and wherein the decoder circuit is configured to provide the inverter control signals, based on the first command signal, to each of the control nodes of each inverter circuit.

8. The signal processing first apparatus of claim 7, wherein each inverter circuit comprises respective pull-up circuitry responsive to a signal at a first control node and each inverter circuit comprises respective pull-down circuitry responsive to a signal at a second control node.

9. The signal processing first apparatus of claim 8, wherein a particular inverter circuit of the multiple parallel-coupled inverter circuits is configured to delay the first input signal when the pull-up and pull-down circuitry are each off, and wherein the particular inverter circuit is configured to change a duty cycle of the first input signal when one of the pull-up and pull-down circuitry is on, and the other one of the pull-up and pull-down circuitry is off.

10. The signal processing first apparatus of claim 1, wherein the first command signal comprises a first command word that defines a magnitude of a delay or duty cycle increase for the first input signal, and the first command signal comprises a second command word that defines a magnitude of a delay or duty cycle decrease for the first input signal.

11. The signal processing first apparatus of claim 1, wherein at least one of the multiple parallel-coupled inverter circuits is biased to an always-on configuration.

12. The signal processing first apparatus of claim 1, wherein at least two of the multiple parallel-coupled inverter circuits are differently weighted.

13. A method comprising:
receiving an AC input signal at a first input node of a delay and duty cycle adjust (DADCA) circuit, wherein the DADCA circuit includes multiple parallel-coupled inverter circuits;
receiving a first command signal;
in response to the first command signal, selectively configuring each of the parallel-coupled inverter circuits of the DADCA circuit for one of no signal adjustment, duty cycle adjustment, or delay signal processing; and
processing the AC input signal using the parallel-coupled inverter circuits and, in response, providing an output signal at a first output node of the DADCA circuit.

14. The method of claim 13, wherein selectively configuring each of the inverter circuits includes configuring at least one of the inverter circuits for duty cycle adjustment and configuring at least one other of the inverter circuits for delay signal processing; and
wherein providing the output signal includes providing a signal that is delayed in time and duty cycle adjusted relative to the AC input signal.

15. The method of claim 13, wherein receiving the first command signal includes:
receiving a multiple-bit command signal at a decoder circuit; and
using the decoder circuit, for each respective bit of the multiple-bit command signal, providing a respective pair of control signals to each inverter circuit of the parallel-coupled inverter circuits of the DADCA circuit.

16. The method of claim 15, wherein when the pair of control signals commands a particular inverter circuit to a high-impedance first state, the output signal is delayed relative to the AC input signal, and
when the pair of control signals commands the particular inverter circuit to a second state, the output signal is duty cycle adjusted relative to the AC input signal.

17. The method of claim 13, wherein receiving the first command signal includes receiving a first multiple-bit command signal indicative of a magnitude of a duty cycle increase and receiving a second multiple-bit command signal indicative of a magnitude of a duty cycle decrease; and
wherein the method further comprises:
using a decoder circuit, for each respective bit of the first multiple-bit command signal, providing corresponding control signals to each of multiple inverter circuits in a first portion of the DADCA circuit, wherein the first portion of the DADCA circuit is configured to process the received AC input signal and provide a first output signal; and
using the decoder circuit, for each respective bit of the second multiple-bit command signal, providing corresponding to control signals to each of multiple inverter circuits in a second portion of the DADCA circuit, wherein the second portion of the DADCA circuit is configured to process a signal complementary to the AC input signal and provide a second output signal.

18. The method of claim 13, comprising:
receiving a complementary input signal at a second input node of the DADCA circuit, wherein first and different second portions of the DADCA circuit are configured to process the AC input signal and the complementary input signal, respectively;
processing the complementary input signal using the second portion of the DADCA circuit; and
providing a complementary output signal at a second output node of the DADCA circuit.

19. A signal processing circuit comprising:
a first delay and duty cycle adjustment (DADCA) circuit comprising:
a first input node configured to receive a first input signal having a first duty cycle; and
a first instance of multiple parallel-coupled inverter circuits coupled to the first input node and to a first output node, wherein each of the inverter circuits comprises a respective pair of control nodes, and wherein the first output node is configured to provide a first output signal based on the first input signal;
a second delay and duty cycle adjustment (DADCA) circuit comprising:
a second input node configured to receive a second input signal that is complementary to the first input signal; and
a second instance of multiple parallel-coupled inverter circuits coupled to the second input node and to a second output node, wherein each of the inverter circuits comprises a respective pair of control nodes, and wherein the second output node is configured to provide a second output signal based on the second input signal; and
a decoder circuit configured to receive a first command signal and, in response, provide respective inverter circuit control signals to each of the control nodes in the first and second instances of the multiple parallel-coupled inverter circuits;
wherein each of the inverter circuits is separately configured by its corresponding control signals from the decoder circuit to change a timing characteristic of the first input signal or the second input signal to provide the first and second output signals.

20. The signal processing circuit of claim 19, wherein the first command signal comprises a first command word that defines a magnitude of a delay or duty cycle adjustment provided by the first DADCA circuit, and the first command signal comprises a second command word that defines a magnitude of a delay or duty cycle adjustment provided by the second DADCA circuit.
